(19) United States
(12) Patent Application Publication
(10) Pub. No.: US 2026/0096159 A1
(43) Pub. Date: Apr. 2, 2026

(54) SEMICONDUCTOR DEVICE WITH REVERSE CURRENT PROTECTION

(71) Applicants: TAIWAN SEMICONDUCTOR MANUFACTURING COMPANY, LTD., Hsinchu (TW); TSMC China Company Limited, Shanghai (CN)

(72) Inventors: David ZHANG, Shanghai City (CN); LinChun GUI, Shanghai City (CN); Jiping ZHU, Shanghai City (CN)

(73) Assignees: TAIWAN SEMICONDUCTOR MANUFACTURING COMPANY, LTD., Hsinchu (TW); TSMC China Company Limited, Shanghai (CN)

(21) Appl. No.: 18/916,389

(22) Filed: Oct. 15, 2024

(30) Foreign Application Priority Data
Sep. 29, 2024 (CN) 202422394432.7

(51) Int. Cl. H01L 29/06; H01L 21/762; H01L 27/07; H01L 29/08; H01L 29/10; H01L 29/45; H01L 29/66; H01L 29/78; H01L 29/872

(52) U.S. Cl. CPC H10D 62/107; H10D 8/60; H10D 30/0277; H10D 62/151; H10D 62/371; H10D 62/393; H10D 62/83; H10D 64/62; H10D 64/647; H10D 84/811; H10P 90/1906; H10W 10/014; H10W 10/061; H10W 10/17; H10W 10/181

(57) ABSTRACT

A semiconductor device includes an n-type buried layer, a first N-well region, a p-type body region, a first source/drain region, a second source/drain region, a gate structure, a second N-well region, and a first silicide region. The n-type buried layer in a substrate. The first N-well region is over the n-type buried layer. The p-type body region abuts the first N-well region. The first source/drain region is in the first N-well region. The second source/drain region is in the p-type body region. The gate structure extends across a boundary of the first N-well region and the p-type body region. The second N-well region is over the n-type buried layer. The first silicide region forms a Schottky contact with the second N-well region.

### PRIORITY CLAIM AND CROSS-REFERENCE

The present application claims priority to China Application Serial Number 202422394432.7, filed Sep. 29, 2024, which is herein incorporated by reference.

### BACKGROUND

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node (e.g., shrink the process node towards the sub-20 nm node). As semiconductor devices are scaled down, new techniques are desired to maintain the electronic components'performance from one generation to the next. For example, low on-resistance and high breakdown voltage of transistors are desirable for various high power applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit (IC) structure having high-voltage (HV) transistors in accordance with some embodiments of the present disclosure.

FIG. 2 is an equivalent circuit diagram of the IC structure as illustrated in FIG. 1.

FIG. 3 is a top view of the IC structure as illustrated in FIG. 1.

FIGS. 4 through 14 illustrate cross-sectional views of intermediate stages in the formation of an IC structure in accordance with some embodiments of the present disclosure.

FIG. 15A illustrates a cross-sectional view of an IC structure in accordance with some embodiments of the present disclosure.

FIG. 15B illustrates a zoomed-in top view of a partial region of the IC structure illustrated in FIG. 15A, in accordance with some embodiments of the present disclosure.

FIG. 16 illustrates a cross-sectional view of an IC structure in accordance with some embodiments of the present disclosure.

FIG. 17 is an equivalent circuit diagram of the IC structure as illustrated in FIG. 16.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

In high-voltage applications, such as overcurrent protection switches, the operation of metal-oxide-semiconductor (MOS) transistors presents a challenge during the transition from the “on” state to the “off” state. The core of the issue lies in the behavior of the inductive load connected to the transistor. Inductive loads store magnetic energy during operation. When the MOS transistor is suddenly turned off, this stored magnetic energy seeks a path to dissipate, leading to the generation of a reverse current. This reverse current flows from the source terminal to the drain terminal of the transistor, primarily through body diodes inherent in the substrate of the IC structure. The flow of a large current through body diodes activates a parasitic bipolar junction transistor (BJT) effect, specifically a parasitic PNP transistor resulting from multiple doped regions (e.g., including P-well, n-type buried layer, and p-type substrate) within the substrate of the IC structure. This activation can result in undesirable leakage currents or, in severe cases, can cause thermal damage to the device, potentially burning it out.

To address the aforementioned problem, the present disclosure in various embodiments involves the integration of a Schottky diode (SBD) or a PN diode into the integrated circuit. This diode is placed in series with the n-type body layer (NBL) directly below the transistor. As such, when the transistor is turned off, the impedance of the path associated with the NBL increases due to the presence of the SBD or PN diode in series. This increased impedance alters the path of the reverse current, favoring the flow through a different circuit loop that is generally irrelevant to the parasitic PNP transistor. By directing the reverse current through this alternate path, the parasitic PNP transistor is prevented from turning on since the conditions that would lead to its activation are mitigated. Consequently, the risks associated with leakage currents and thermal damage are significantly reduced, preserving the integrity and functionality of the transistors in high-voltage applications.

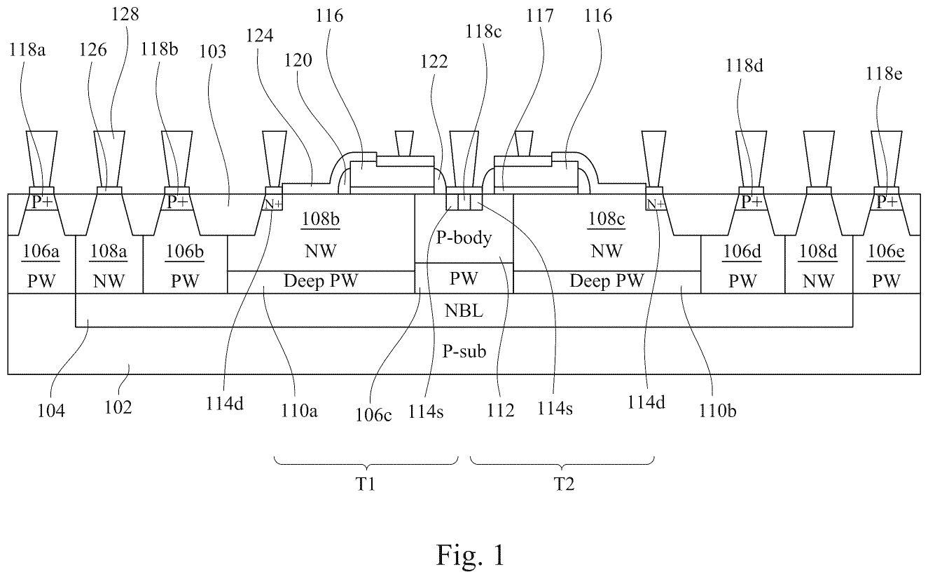

FIG. 1 is a cross-sectional view of an integrated circuit (IC) structure having high-voltage (HV) transistors (e.g., adjacent HV transistors T1 and T2) in accordance with some embodiments of the present disclosure. HV transistors T1, T2 are semiconductor devices serving to switch or amplify high voltage signals. These transistors T1, T2 are engineered to handle and control electrical power significantly higher than standard transistors, making them suitable in applications that require the management of high voltage levels. The ability to operate at high voltages allows these transistors T1, T2 to be used in a variety of power electronics, including power supplies, inverters, and overcurrent protection circuits.

The HV transistors T1 and T2 are formed on a semiconductor substrate 102. The semiconductor substrate 102 may include a semiconductor wafer such as a silicon wafer. Alternatively, the semiconductor substrate 102 may include other elementary semiconductors such as germanium. The semiconductor substrate 102 may also include a compound semiconductor such as silicon carbide, gallium arsenic, indium arsenide, and indium phosphide. Moreover, the semiconductor substrate 102 may include an alloy semiconductor such as silicon germanium, silicon germanium carbide, gallium arsenic phosphide, and gallium indium phosphide. In some embodiments, the semiconductor substrate 102 includes a p-type silicon substrate (p-substrate), labeled “P-sub” in FIG. 1.

A plurality of isolation regions 103, such as shallow trench isolation (STI) regions or local oxidation of silicon (LOCOS) (or field oxide, FOX) regions including isolation features, may be formed in the substrate 102 to define and electrically isolate various active regions so as to prevent leakage current from flowing between adjacent active regions.

Situated within the substrate 102, and beneath the STI regions 103, is an n-type buried layer 104, labeled “NBL” in FIG. 1. This layer 104 is buried beneath other doped regions (e.g., well regions) in the substrate 102, hence the term “buried.” In some embodiments, the NBL 104 is formed by implanting an n-type dopant such as phosphorus or arsenic into a predetermined region within the substrate 102, serving to isolate devices from the substrate 102.

Within the confines of the STI regions 103, several well regions are formed, including P-well regions 106a through 106e, which are labeled “PW” in FIG. 1, and N-well regions 108a through 108d, which are labeled “NW” in FIG. 1. These well regions are doped regions where P-well regions 106a-106e are doped with p-type dopants (e.g., boron, boron fluoride, indium, or the like) and N-well regions 108a-108d are doped with n-type dopants (e.g., phosphorus, arsenic, antimony, or the like). The P-well regions 106a-106e are alternately arranged with the N-well regions 108a-108d. Stated differently, the P-well regions 106a-106e and N-well regions 108a-108d are positioned in an alternating sequence, which means that each P-well regions is followed by an N-well region, and vice versa, in a horizontal direction throughout the substrate 102. In some embodiments, the HV transistor T1 has a footprint on the N-well region 108b, and the HV transistor T2 has a footprint on the N-well region 108c.

In some embodiments, deep P-well regions 110a and 110b, labeled “Deep PW” in FIG. 1, are formed deeper within the substrate 102, further enhancing the isolation properties of the IC structure. The deep P-well regions 110a and 110b are respectively buried below the N-well regions 108b and 108c. These deep P-well regions 110a and 110b are heavily doped with p-type dopants and are beneficial in preventing latch-up by providing robust isolation between n-type regions of the IC structure.

Located between the N-well region 108b and the N-well region 108c, a p-type body region 112 is provided, which forms channel regions for the abutting n-type HV transistors T1 and T2. The p-type body region 112 is labeled “P-body” in FIG. 1. An n-type source region 114s of the HV transistor T1 and an n-type source region 114s of the HV transistor T2 are formed in the p-type body region 112. An n-type drain region 114d of the HV transistor T1 and an n-type drain region 114d of the HV transistor T2 are formed in the N-well regions 108b and 108c, respectively. The n-type source region 114s and drain region 114d can be collectively referred to as n-type source/drain regions 114s/114d, labeled “N+” in FIG. 1, which allow for the flow of electrons from the source region to the drain region under the control of a corresponding gate electrode 116 of the HV transistor. Source/drain region may refer to a source region or a drain region, individually or collectively dependent upon the context.

The gate electrodes 116 of the transistors T1 and T2 are disposed over the channel regions defined by the p-type body region 112. In some embodiments, the gate electrodes 116 are formed from conductive materials such as polysilicon or metal. The gate electrodes 116 are separated from the channel regions within the p-type body region 112 by respective gate dielectric layers 117, which may comprise silicon dioxide or a high-k material, serving to insulate the gate electrode 116 and ensures effective control over the transistor by modulating the electrical field within the channel regions. In some embodiments, the gate electrode 116 of transistor T1 laterally extends from above the p-type body region 112 to above the N-well region 108b, and the gate electrode 116 of the transistor T2 laterally extends from above the p-type body region 112 to above the N-well region 108c. In some embodiments, the gate electrode 116 extends a gate length from the p-type body region 112 to the N-well region 108b or 108c, and the gate length is in a range from about 0.7 μm to about 3 μm.

Encapsulating sidewalls of the gate electrode 116 are gate spacers 120 and 122, formed from dielectric materials such as silicon nitride or oxide. The gate spacers 122 define lateral boundaries of the source regions 114s and protect the gate sidewalls during ion implantation processes, thereby maintaining the integrity of the gate structure.

In some embodiments, resist protection oxide (RPO) layer 124 are formed over the respective gate electrodes 116. The RPO layers 124 can function as a silicide blocking layer during a subsequent self-aligned silicidation (or also called salicide) process. More particularly, the RPO layers 124 cover surfaces that will not be formed with silicide. In greater detail, the RPO layers 124 cover partial regions of respective gate electrodes 116 and partial regions of respective N-well regions 108b, 108c, while exposing partial regions of respective gate electrodes 116 and partial regions of respective N-well regions 108b, 108c for forming silicide regions 126.

Heavily doped p-type regions 118a, 118b, 118d, and 118e are formed in P-well regions 106a, 106b, 106d, and 106d, respectively. A heavily doped p-type region 118c is formed in the p-type body region 112 and laterally between the source regions 114s of the abutting transistors T1, T2. The heavily doped p-type regions, labeled “P+” in FIG. 1, have a suitable dopant concentration serving to form an ohmic contact with metal elements in the corresponding metal silicide regions 126 and metal contacts 128. The dopant concentration in these heavily doped p-type regions is meticulously controlled to ensure a minimal barrier for electron flow, thereby facilitating an efficient charge transfer process. An ohmic contact refers to an electrical junction between two materials (e.g., between semiconductor and metal) through which current can flow easily in both directions without significant barrier. This type of contact exhibits a linear current-voltage (I-V) relationship, meaning the resistance remains constant regardless of the direction of current flow. This is in contrast to a rectifying contact (e.g., Schottky contact), where the I-V characteristics are nonlinear, and the contact acts more like a diode (also called Schottky diode (SBD)), allowing current to flow more easily in one direction than the other.

The heavily doped p-type regions 118a-118e have a higher p-type impurity concentration than the P-well regions 106a-106e, so as to form ohmic contact by using the heavily doped p-type regions 118a-118e. Similarly, n-type drain regions 114d have a higher n-type impurity concentration than the N-well regions 108a-108d, and n-type source regions 114s have a higher n-type impurity concentration than the p-type body region 112, so as to form ohmic contact by using the n-type source/drain regions 114s/114d. In some embodiments, each source/drain region 114s/114d has a width in a range from about 0.4 μm to about 2 μm. In some embodiments, the SIT region 103 between the drain region 114d and the heavily doped p-type region 118b has a width in a range from about 6 μm to about 7 μm.

Silicide regions 126 are formed over the n-type source/drain regions 114s/114d, the heavily doped p-type regions 118a-118e, the N-well regions 108a, 108d, and the gate electrodes 116 to reduce the contact resistance between these regions and the overlying contacts 128. Contacts 128 are formed over the respective silicide regions 126 to provide the electrical connections between the transistors T1, T2 and other circuit elements. The source regions 114s of the transistors T1 and T2 and the interposing heavily doped p-type region 118c share a same silicide region 126 and a same contact 128.

In FIG. 1, the N-well region 108a is in direct contact with a silicide region 126, and the N-well region 108d is in direct contact with another silicide region 126. Because the N-well regions 108a and 108d have a lower dopant concentration (i.e., impurity concentration) than the source/drain regions 114s/114d and the heavily doped p-type regions 118a-118e, the N-well regions 108a, 108d form Schottky contacts with the overlying metal elements in the silicide regions 126 and metal contacts 128, rather than ohmic contacts. In some embodiments, a ratio of a dopant concentration in the source/drain regions 114s/114d (i.e., the N+ regions) to a dopant concentration in the N-well regions 108a, 108d is in a range from about 10 to 1000. Stated differently, the dopant concentration in the N-well regions 108a, 108d is at least one order of magnitude less than the dopant concentration in the source/drain regions 114s/114d. Due to the dopant concentration difference, the N-well regions 108a, 108d can form Schottky contacts with overlying metal elements, and the source/drain regions 114s/114d can form ohmic contacts with overlying metal elements.

A Schottky contact refers to the junction formed between a metal and a semiconductor material. The Schottky contact exhibits an unidirectional current flow characteristic, which allows electrons to move more freely in one direction than the other, creating a rectifying behavior. This is primarily due to the difference in work function between semiconductor (i.e., the semiconductor elements in N-well regions 108a, 108d) and metal (i.e., metal elements in the silicide region 126 and the metal contact 128). By utilizing the Schottky contacts, Schottky diodes are created at junctions between the N-well regions 108a, 108d and the silicide regions 126. Because the N-well regions 1080a, 108d are in direct contact with a top surface of the NBL 104, the Schottky diodes are connected in series with the NBL 104, serving to prevent unintentional activation of a parasitic PNP transistor (e.g., a PNP transistor formed from deep P-well region 110a/110b, NBL 104 and p-type substrate 102), as will be discussed in greater detail below. In some embodiments where the HV transistors T1 and T2 have an operation voltage of about 55 volts, a lateral dimension of the Schottky diode is about 0.4 μm to about 0.6 μm. Stated differently, a width of a top surface of the N-well region 108a is in a range from about 0.4 μm to about 0.6 μm.

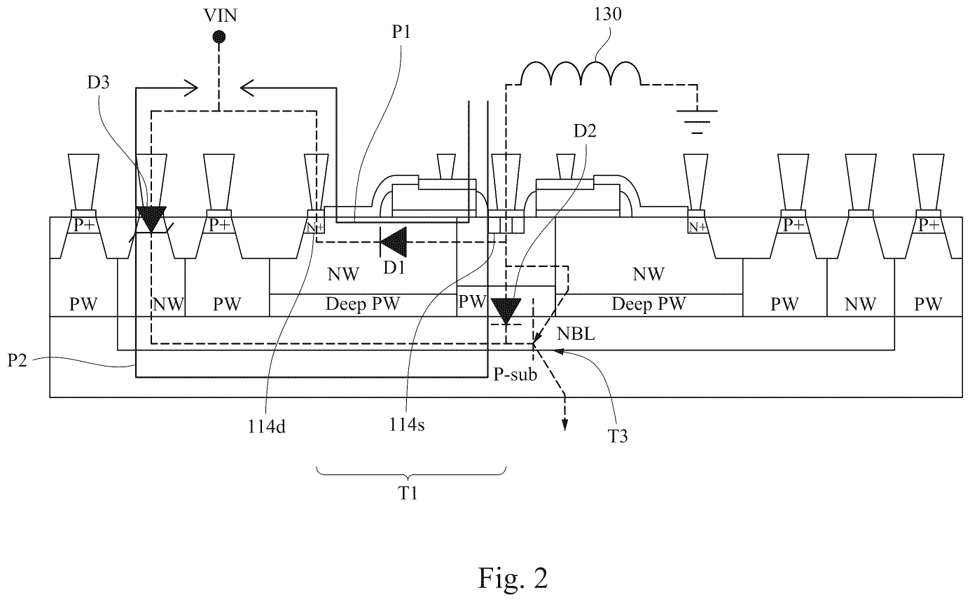

FIG. 2 is an equivalent circuit diagram of the IC structure as illustrated in FIG. 1. FIG. 2 illustrates a high-voltage overcurrent protection switch circuit in accordance with some embodiments of the present disclosure. This circuit includes a HV transistor T1 having a source terminal (i.e., the source region 114s) electrically connected to an inductive load 130, and a drain terminal electrically connected to an input voltage terminal (VIN). The inductive load 130 is a two-terminal device with a first terminal connected to the source terminal of the HV transistor T1 and a second terminal connected to ground. In some embodiments, the inductive load 130 is a coil or an inductor, which stores energy in the form of a magnetic field when current flows through them. This characteristic allows for operations of various devices and circuits, including boost converters, fly-back converters, H-bridge motor drivers, and LLC resonant converters, among others. These applications leverage the properties of inductors to perform functions such as voltage conversion, energy transfer, and motor control. For instance, a boost converter increases input voltage to a higher output voltage, a fly-back converter provides galvanic isolation and voltage transformation, an H-bridge allows for direction control of motors, and an LLC resonant converter offers efficient power conversion with minimal loss.

When the HV transistor T1 is turned off, the magnetic energy stored in the inductive load 130 seeks a path to dissipate, leading to a reverse current that flows from the inductive load 130 back towards the input voltage terminal VIN. This reverse current can traverse through two paths, labeled P1 and P2. The path P1 runs through a body diode D1 formed from the PN junction of the p-type body region 112 and the N-well region 108b. The path P1 then runs through the n-type drain region 114d and its overlying contact to the input voltage terminal VIN. The path P2 runs through another body diode D2 formed from the PN junction of the P-well region 106c and the NBL 104. The path P2 then runs through the N-well region 108a and its overlying contacts to the input voltage terminal VIN. When the current flows along the path P2, the current flow may inadvertently activate a parasitic PNP transistor T3, which is formed from the deep P-well region 110b, the NBL 104, and the p-type substrate 102. Activation of the parasitic PNP transistor T3 could result in undesirable leakage currents. However, this risk is mitigated by the presence of a Schottky diode D3, formed from the semiconductor element in the N-well region 108a and the overlying metal element. When the Schottky diode D3 is connected in series with the NBL 104 on path P2, the impedance of path P2 significantly increases compared to path P1. This increased impedance effectively discourages current flow through path P2, thereby circumventing the activation of the parasitic PNP transistor T3. As a result, the potential issues related to leakage currents can be reduced.

Moreover, when the HV transistor T1 is turned on, the existence of the Schottky diode D3 does not adversely impact the circuit's performance. This is due to that the forward voltage drop of the Schottky diode D3, which is connected to the drain terminal of the HV transistor T1, is low. In some embodiments, the forward voltage of the Schottky diode D3 is in a range from about 0.1 volt to about 0.3 volt.

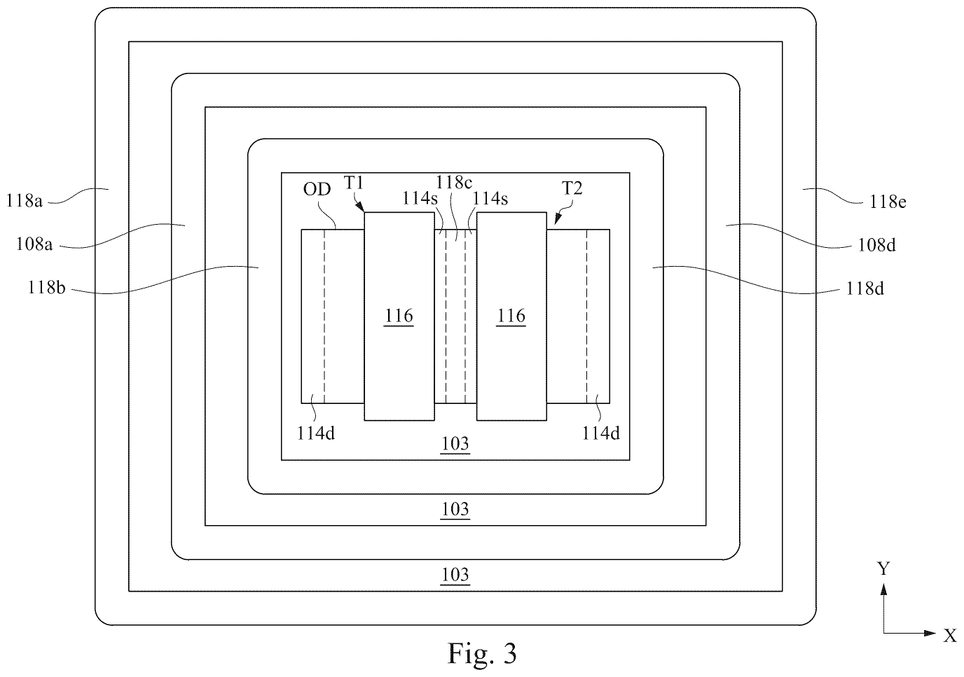

FIG. 3 is a top view of the IC structure as illustrated in FIG. 1. In the top view, an active region OD has a rectangular pattern extending along X-direction, and the gate electrodes 116 have rectangular patterns extending across the active region OD along Y-direction perpendicular to X-direction. The source/drain regions 114s/114d, and heavily doped p-type region 118c are formed in the active region and extend in Y-direction. From the top view, a first STI region 103 has a continuous ring-shaped pattern surrounding the active region OD and the gate electrodes 116, the heavily doped p-type regions 118b and 118d collectively form a continuous ring-shaped pattern surrounding the first STI region 103, a second STI region 103 has a continuous ring-shaped pattern surrounding the heavily doped p-type regions 118b and 118d, the N-well regions 108a and 108d collectively form a continuous ring-shaped pattern surrounding the second STI region 103, a third STI region 103 has a continuous ring-shaped pattern surrounding the N-well regions 108a and 108d, and the heavily doped p-type regions 118a and 118e collectively form a continuous ring-shaped pattern surrounding the third STI region 103.

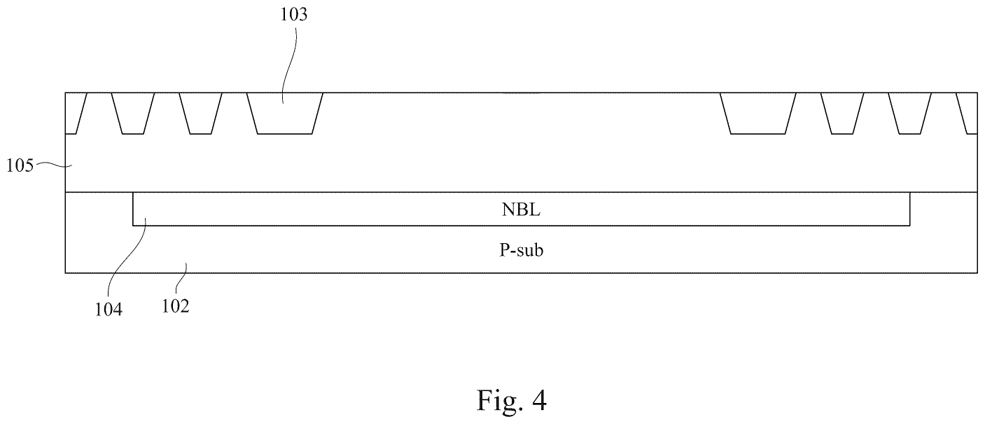

FIGS. 4 through 14 illustrate cross-sectional views of intermediate stages in the formation of an IC structure in accordance with some embodiments of the present disclosure. Throughout the various views and illustrative embodiments, like reference numbers are used to designate like elements. It is understood that additional operations can be provided before, during, and after the processes shown by FIGS. 4-14, and some of the operations described below can be replaced or eliminated, for additional embodiments of the method. The order of the operations/processes may be interchangeable.

FIG. 4 illustrates a cross-sectional view of an initial structure. The initial structure includes a semiconductor substrate 102. The semiconductor substrate 102 may include a semiconductor wafer such as a silicon wafer. Alternatively, the semiconductor substrate 102 may include other elementary semiconductors such as germanium. The semiconductor substrate 102 may also include a compound semiconductor such as silicon carbide, gallium arsenic, indium arsenide, and indium phosphide. Moreover, the semiconductor substrate 102 may include an alloy semiconductor such as silicon germanium, silicon germanium carbide, gallium arsenic phosphide, and gallium indium phosphide. In some embodiments, the semiconductor substrate 102 includes a p-type silicon substrate (p-substrate), labeled “P-sub” in FIG. 4. In some embodiments, the p-type substrate 102 has a thickness in a range from about 500 μm to about 10000 μm, and a resistivity in a range from about 10 ohm-cm to about 100 ohm-cm.

FIG. 4 also illustrates an NBL 104 formed in the substrate 102. The NBL 104 can be formed by, for example, a photolithography process followed by an ion implantation process. For example, a patterned mask layer can be formed over the substrate 102 to define a location of the NBL 104 subsequently formed in the substrate 102. The patterned mask layer may comprise an organic material, such as a photoresist material, and may be formed using a spin-on coating process, followed by patterning the photoresist material, using suitable lithography techniques, to forming one or more openings extending through the patterned mask layer to expose a target region of the substrate 102. For example, photoresist material is irradiated (exposed) and developed to remove portions of the photoresist material. In greater detail, a photomask (not shown) may be placed over the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material, and a developer may be used to remove either the exposed or unexposed portions of the photoresist material depending on whether a positive or negative resist is used.

Next, with the patterned mask layer in place, an n-type ion implantation process is performed to dope an n-type impurity (e.g., phosphorus, arsenic, antimony, or the like) into the p-type substrate 102 to form the NBL 104. The n-type ion implantation is performed using the patterned mask layer as an implantation mask, such that the NBL 104 has a top-view pattern or geometry inheriting the top-view pattern or geometry of the opening of the patterned mask layer. In this way, the top-view pattern of the opening can be designed to define a desired top-view pattern of the NBL 104. In some embodiments, the n-type ion implantation process for the NBL 104 is performed to implant the n-type impurity at a dose of about 1E13 atoms/cm² to about 1E14 atoms/cm², and at an energy of about 50 KeV to about 100 KeV.

After forming the NBL 104, the patterned mask layer is removed, for example, using a plasma ash process. In some embodiments, a plasma ash process is performed such that the temperature of the photoresist mask is increased until the photoresist mask experiences a thermal decomposition and may be removed. However, any other suitable process, such as a wet strip, may be utilized.

Afterwards, a p-type epitaxial layer 105 is formed over the p-type substrate 102 and the NBL 104. In some embodiments, the p-type epitaxial layer 105 is a crystalline semiconductor material (e.g., silicon, germanium, or silicon germanium) formed using a suitable epitaxial growth method such as e.g., vapor/solid/liquid phase epitaxy (VPE, SPE, LPE), or metal-organic CVD (MOCVD), or molecular beam epitaxy (MBE), or the like. A dose of p-type impurity (e.g., boron, boron fluoride, indium, or the like) is introduced into the epitaxially grown material either in situ during the epitaxial growth, or by an ion implantation process performed after the epitaxial growth, or by a combination thereof. In some embodiments, the p-type epitaxial layer 105 has a thickness in a range from about 5 μm to about 10 μm, and a resistivity in a range from about 10 ohm-cm to about 100 ohm-cm, which aids in preventing leakage and improving breakdown voltage.

After the p-type epitaxial layer 105 is formed, isolation structures 103 such as shallow trench isolation (STI) regions or local oxidation of silicon (LOCOS) (or field oxide, FOX) regions including isolation features are formed in the p-type epitaxial layer 105 to define and electrically isolate various active regions so as to prevent leakage current from flowing between adjacent active regions. As one example, the formation of an STI feature may include dry etching a trench in a substrate and filling the trench with insulator materials such as silicon oxide, silicon nitride, or silicon oxynitride. The filled trench may have a multi-layer structure such as a thermal oxide liner layer filled with silicon nitride or silicon oxide. In some other embodiments, the STI structure may be created using a processing sequence such as: growing a pad oxide, forming a low pressure chemical vapor deposition (LPCVD) nitride layer, patterning an STI opening using photoresist and masking, etching a trench in the substrate, optionally growing a thermal oxide trench liner to improve the trench interface, filling the trench with CVD oxide, using chemical mechanical polishing (CMP) processing to etch back and planarize, and using a nitride stripping process to remove the silicon nitride.

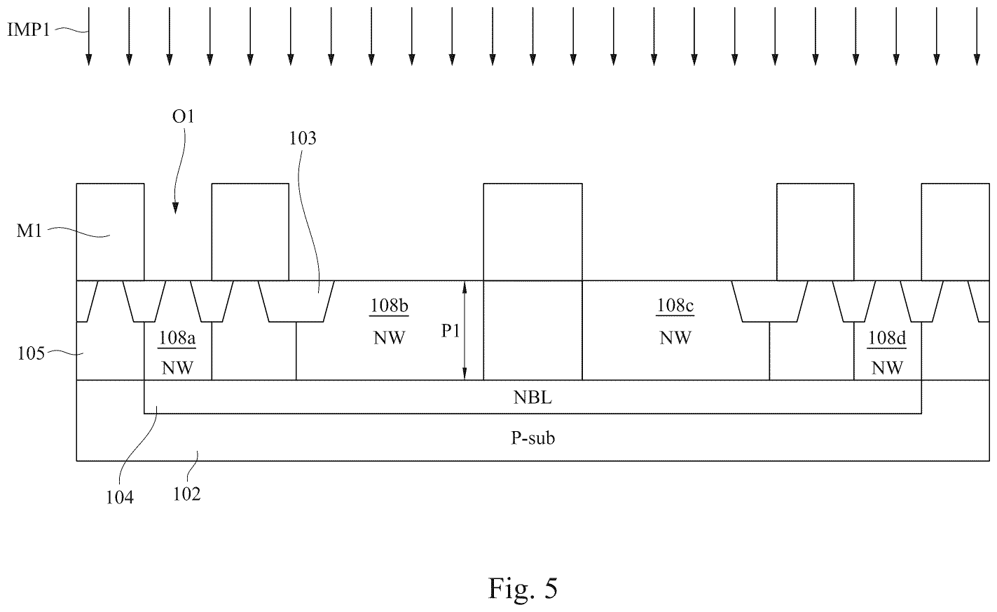

In FIG. 5, a patterned mask layer M1 is formed over the p-type epitaxial layer 105 to define locations of N-well regions 108a formed in subsequent implantation processing. The patterned mask layer M1 may comprise an organic material, such as a photoresist material, and may be formed using a spin-on coating process, followed by patterning the photoresist material, using suitable lithography techniques, to forming one or more openings O1 extending through the patterned mask layer M1 to expose N-well target regions within the p-type epitaxial layer 105. For example, photoresist material is irradiated (exposed) and developed to remove portions of the photoresist material. In greater detail, a photomask (not shown) may be placed over the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material, and a developer may be used to remove either the exposed or unexposed portions of the photoresist material depending on whether a positive or negative resist is used.

Next, with the patterned mask layer M1 in place, an n-type ion implantation process IMP1 is performed to dope an n-type impurity (e.g., phosphorus, arsenic, antimony, or the like) into the p-type epitaxial layer 105 to form N-well regions 108a-108d. These N-well regions 108a-108d can be collectively referred to as N-well regions 108. The n-type ion implantation IMP1 is performed using the patterned mask layer M1 as an implantation mask, such that each N-well region 108 has a top-view pattern or geometry inheriting the top-view pattern or geometry of the corresponding opening O1 of the patterned mask layer M1. In this way, the top-view patterns of the openings O1 can be designed to define desired top-view patterns of the N-well regions 108a-108d. In some embodiments, the n-type ion implantation process IMP1 is performed to implant the n-type impurity at a dose of about 1E12 atoms/cm² to about 1E13 atoms/cm², and at an energy of about 50 KeV to about 3000 KeV.

In some embodiments, the N-well regions 108a-108d have an n-type impurity concentration less than an n-type impurity concentration of the NBL 104, for example, by at least one order of magnitude. In some embodiments, the pattern of the patterned mask layer M1 is designed in such a way that all of N-well regions 108a-108d vertically overlaps with the NBL 104. In particular, the NBL 104 has a right sidewall boundary aligned with a right sidewall boundary of the N-well region 108d, and the NBL 104 has a left sidewall boundary aligned with a left sidewall boundary of the N-well region 108a. The NBL 104 is thus electrically coupled with the N-well regions 108a-108d, which allows for electrically connecting the NBL 104 in series with Schottky diodes formed in the N-well regions 108a and 108d. In some embodiments, each N-well region 108 has a depth P1 substantially the same as the thickness of the p-type epitaxial layer 105. Stated differently, each N-well region 108 extends vertically through a full thickness of the p-type epitaxial layer 105 and terminates the top surface of the NBL 104.

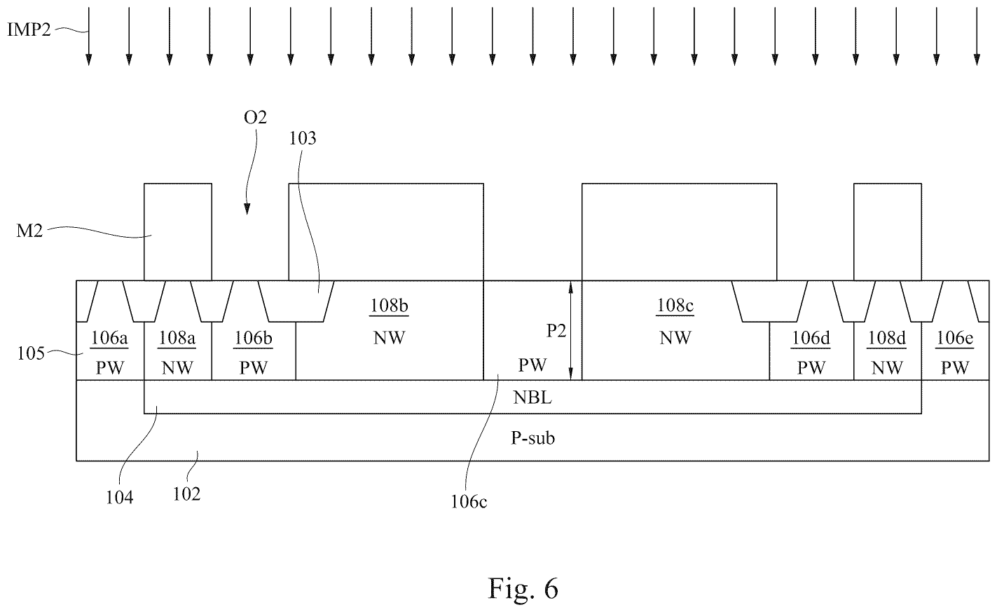

In FIG. 6, after forming N-well regions 108, the patterned mask layer M1 is removed, for example, using a plasma ash process. In some embodiments, a plasma ash process is performed such that the temperature of the photoresist mask M1 is increased until the photoresist mask M1 experiences a thermal decomposition and may be removed. However, any other suitable process, such as a wet strip, may be utilized.

Next, another patterned mask layer M2 is formed over the p-type epitaxial layer 105 to define locations of P-well regions 106 formed in subsequent processing. The patterned mask layer M2 may comprise an organic material, such as a photoresist material, and may be formed using a spin-on coating process, followed by patterning the photoresist material, using suitable lithography techniques, to forming one or more openings O2 extending through the patterned mask layer M2 to expose P-well target regions within the p-type epitaxial layer 105. For example, photoresist material is irradiated (exposed) and developed to remove portions of the photoresist material. In greater detail, a photomask (not shown) may be placed over the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material, and a developer may be used to remove either the exposed or unexposed portions of the photoresist material depending on whether a positive or negative resist is used.

Next, with the patterned mask layer M2 in place, a p-type ion implantation process IMP2 is performed to dope a p-type impurity (e.g., boron, boron fluoride, indium, or the like) into the p-type epitaxial layer 105 to form P-well regions 106a-106e alternating with the N-well regions 108a-108d. The p-type ion implantation IMP2 is performed using the patterned mask layer M2 as an implantation mask, such that each P-well region 106 has a top-view pattern or geometry inheriting the top-view pattern or geometry of the corresponding opening O2 of the patterned mask layer M2. In this way, the top-view pattern of the opening O2 can be designed to define a desired top-view pattern of the P-well region 106. In some embodiments, the p-type ion implantation process IMP3 is performed to implant the p-type impurity at a dose of about 1E12 atoms/cm² to about 1E13 atoms/cm², and at an energy of about 50 KeV to about 3000 KeV.

In some embodiments, each of the P-well regions 106a-106e each has a p-type impurity concentration less than an n-type impurity concentration of the NBL 104 by, for example, at least one order of magnitude. In some embodiments, the pattern of the patterned mask layer M2 is designed in such a way that P-well regions 106b, 106c, and 106d vertically overlaps with the NBL 104, while P-well region 106a and 106e non-overlaps with the NBL 104. In some embodiments, each P-well region 106 has a depth P2 substantially the same as the thickness of the p-type epitaxial layer 105. Stated differently, the P-well region 106 extends vertically through a full thickness of the p-type epitaxial layer 105 and terminates the top surface of the p-type substrate 102 or the top surface of the NBL 104. Because the N-well regions 108 also extend vertically through a full thickness of the p-type epitaxial layer 105, the bottom surfaces of the N-well regions 108 are level with the bottom surfaces of the P-well regions 106. In some embodiments, after the ion implantation process, an anneal process may be performed on the substrate 102 to activate the dopants in the well regions.

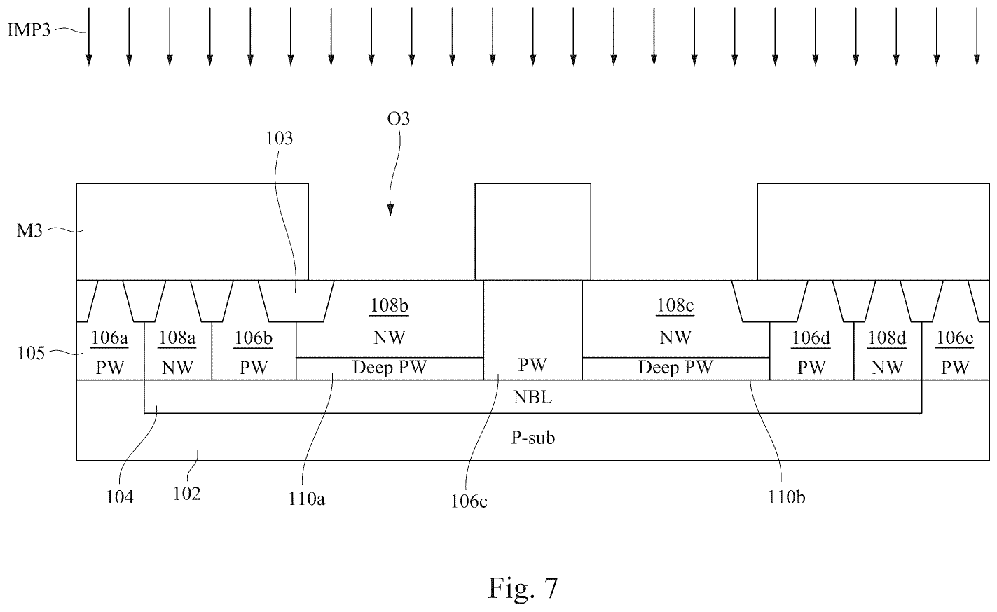

In FIG. 7, after forming P-well regions 106, the patterned mask layer M2 is removed, for example, using a plasma ash process. In some embodiments, a plasma ash process is performed such that the temperature of the photoresist mask M2 is increased until the photoresist mask M2 experiences a thermal decomposition and may be removed. However, any other suitable process, such as a wet strip, may be utilized.

Next, another patterned mask layer M3 is formed over the p-type epitaxial layer 105 to define locations of deep P-well regions 110a and 110b formed in subsequent implantation processing. The patterned mask layer M3 may comprise an organic material, such as a photoresist material, and may be formed using a spin-on coating process, followed by patterning the photoresist material, using suitable lithography techniques, to forming one or more openings O3 extending through the patterned mask layer M3 to expose deep P-well target regions within the p-type epitaxial layer 105. For example, photoresist material is irradiated (exposed) and developed to remove portions of the photoresist material. In greater detail, a photomask (not shown) may be placed over the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material, and a developer may be used to remove either the exposed or unexposed portions of the photoresist material depending on whether a positive or negative resist is used.

Next, with the patterned mask layer M3 in place, a p-type ion implantation process IMP3 is performed to dope a p-type impurity (e.g., boron, boron fluoride, indium, or the like) into the p-type epitaxial layer 105 to form deep P-well regions 110a and 110b at positions directly below the N-well regions 108b and 108c. The p-type ion implantation IMP3 is performed using the patterned mask layer M3 as an implantation mask, such that each deep P-well region 110a, 110b has a top-view pattern or geometry inheriting the top-view pattern or geometry of the corresponding opening O3 of the patterned mask layer M3. In this way, the top-view patterns of the openings O3 can be designed to define a desired top-view pattern of the deep P-well regions 110a, 110b. In some embodiments, the p-type ion implantation process IMP3 is performed to implant the p-type impurity at a dose of about 1E12 atoms/cm² to about 1E13 atoms/cm², and at an energy of about 200 KeV to about 500 KeV.

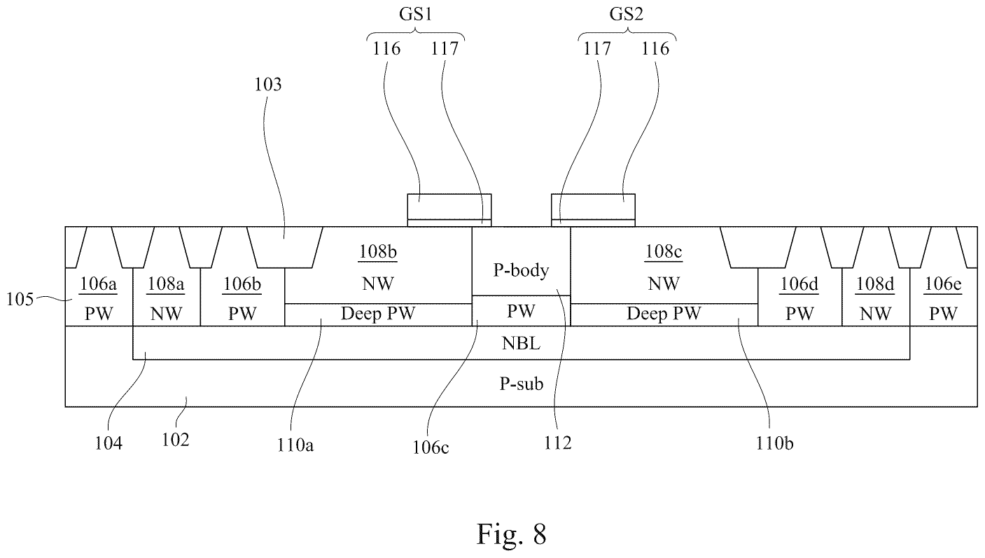

In FIG. 8, a p-type body region 112 is formed in the P-well region 106c. The p-type body region 112 can be formed by, for example, a photolithography process followed by an ion implantation process. For example, a patterned mask layer can be formed over the substrate 102 to define a location of the p-type body region 112 subsequently formed in the substrate 102. The patterned mask layer may comprise an organic material, such as a photoresist material, and may be formed using a spin-on coating process, followed by patterning the photoresist material, using suitable lithography techniques, to forming one or more openings extending through the patterned mask layer to expose a target region of the substrate 102. For example, photoresist material is irradiated (exposed) and developed to remove portions of the photoresist material. In greater detail, a photomask (not shown) may be placed over the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material, and a developer may be used to remove either the exposed or unexposed portions of the photoresist material depending on whether a positive or negative resist is used.

Next, with the patterned mask layer in place, a p-type ion implantation process is performed to dope a p-type impurity (e.g., boron, boron fluoride, indium, or the like) into the P-well region 106c to form a p-type body region 112. The p-type ion implantation is performed using the patterned mask layer as an implantation mask, such that the p-type body region 112 has a top-view pattern or geometry inheriting the top-view pattern or geometry of the corresponding opening of the patterned mask layer. In this way, the top-view pattern of the opening can be designed to define a desired top-view pattern of the p-type body region 112. In some embodiments, the p-type ion implantation process is performed to implant the p-type impurity at a dose of about 1E13 atoms/cm² to about 1E14 atoms/cm², and at an energy of about 30 KeV to about 300 KeV. In some embodiments, the p-type body region 112 has a width in a range from about 1.1 μm to about 1.6 μm. Because the p-type body region 112 is implanted with p-type impurity at two implantation steps, including the ion implantation process IMP2 and the ion implantation process of forming the p-type body region 112, the p-type body region 112 has a higher p-type impurity concentration than the P-well regions 106a-106e.

After forming the p-type body region 112, gate structures GS1 and GS2 are formed over the substrate 102. In particular, gate dielectric layers 117 are formed over the p-type body region 112, followed by forming gate electrodes 116 over the respective gate dielectric layers 117. A gate dielectric layer 117 and an overlying gate electrode 116 collectively serve as a gate structure GS1 extending from over the p-type body region 112 to over the N-well region 108b. A gate dielectric layer 117 and an overlying gate electrode 116 collectively serve as a gate structure GS2 extending from over the p-type body region 112 to over the N-well region 108c. In some embodiments, the gate structures GS1 and GS2 are formed by, for example, growing an oxide layer on top surface of the p-type epitaxial layer 105 using a thermal oxidation process or an in-situ steam generation (ISSG) process, depositing a gate electrode layer over the oxide layer, followed by patterning the gate electrode layer and the oxide layer into gate electrodes 116, and gate dielectric layers 117 using suitable photolithography and etching techniques.

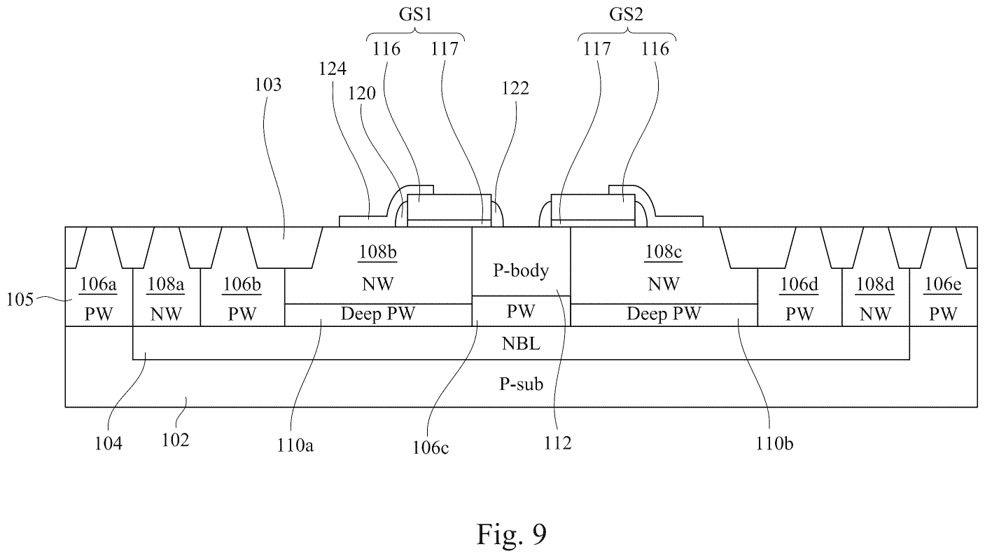

In FIG. 9, gate spacers 120 and 122 are formed on opposite sidewalls of the gate structures GS1, GS2. Spacers 120 and 122 can be formed by, for example, conformally forming one or more layers of spacer materials on p-type epitaxial layer 105 by using suitable deposition techniques (e.g., CVD, ALD, or combinations thereof), followed by etching the one or more layers of spacer materials by using an anisotropic etching process. The anisotropic etching process removes horizontal portions of the one or more layers of spacer materials, while leaving vertical portions of the one or more layers of spacer materials on sidewalls of the gate structures GS1 and GS2. The remaining spacer materials on N-well regions 108b can be referred to as gate spacers 120, and remaining spacer materials on the p-type body region 112 can be referred to as gate spacers 122. In some embodiments, the anisotropic etching for forming the gate spacers is an RIE process using a plasma produced from CHF₃ gas and/or Cl₂ gas. In some embodiments, The gate spacers 120 and 122 include silicon nitride (Si₃N₄), although other materials, such as silicon oxynitride, silicon carbide, silicon carbonitride, silicon oxycarbonitride, silicon oxycarbide, porous dielectric materials, hydrogen doped silicon oxycarbide (SiOC:H), low-k dielectric materials, or other suitable dielectric materials, may be used.

After forming the gate spacers 120 and 122, resist protection oxide (RPO) layers 124 are formed respectively the gate structures GS1 and GS2. An RPO layer 124 is formed to cover a partial region of a top surface of the gate electrode 116 of the gate structure GS1, while leaving another region of the top surface of the gate electrode 116 exposed. An RPO layer 124 is formed to cover a partial region of a top surface of the gate electrode 116 of the gate structure GS2, while leaving another region of the top surface of the gate electrode 116 exposed. The RPO layers 124 laterally extend along top surfaces of the N-well regions 108b and 108c, and terminate prior to reaching the STI regions 103. The RPO layers 124 can be formed by, for example, depositing an oxide layer (e.g., SiO₂ layer) over the gate structures GS1, GS2 and the p-type epitaxial layer 105, followed by patterning the oxide layer into the RPO layers 124 by using suitable etching techniques (e.g., dry etching, wet etching or combinations thereof). The RPO layers 124 may function as a silicide blocking layer during a subsequent self-aligned silicidation (or also called salicide) process.

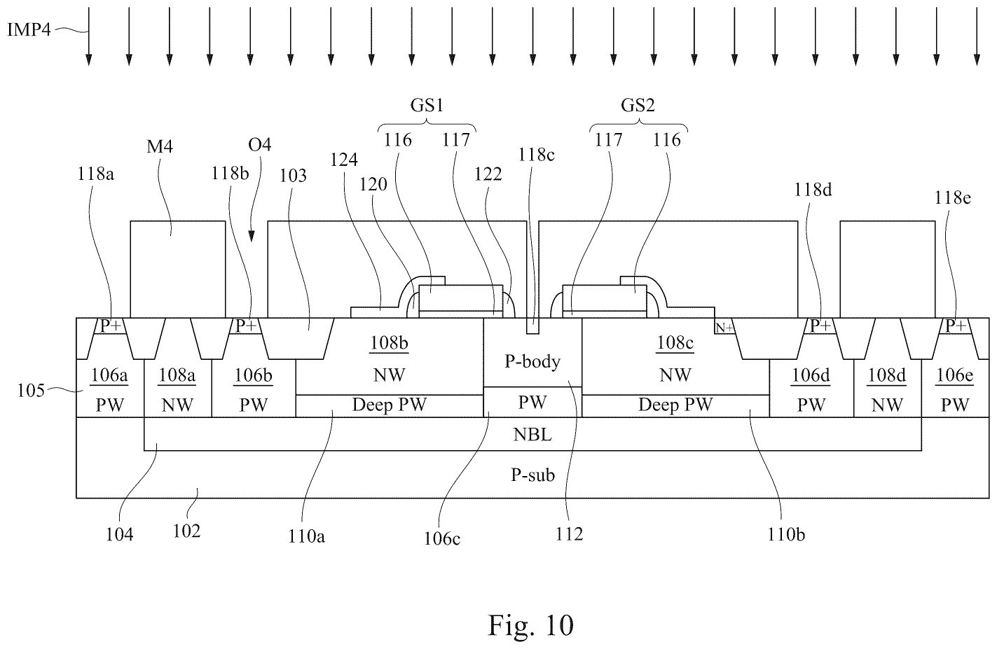

In FIG. 10, patterned mask layer M4 is formed over the p-type epitaxial layer 105 to define locations of heavily doped p-type regions 118a-118e formed in subsequent processing. The patterned mask layer M4 may comprise an organic material, such as a photoresist material, and may be formed using a spin-on coating process, followed by patterning the photoresist material, using suitable lithography techniques, to forming one or more openings O4 extending through the patterned mask layer M4 to expose target regions within the p-type epitaxial layer 105. For example, photoresist material is irradiated (exposed) and developed to remove portions of the photoresist material. In greater detail, a photomask (not shown) may be placed over the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material, and a developer may be used to remove either the exposed or unexposed portions of the photoresist material depending on whether a positive or negative resist is used.

Next, with the patterned mask layer M4 in place, a p-type ion implantation process IMP4 is performed to dope a p-type impurity (e.g., boron, boron fluoride, indium, or the like) into the p-type epitaxial layer 105 to form heavily doped p-type regions 118a, 118b, 118d, and 118e in the P-well regions 106a, 106b, 106d, 106e, respectively, and to form a heavily doped p-type region 118c in the p-type body region 112. The p-type ion implantation IMP4 is performed using the patterned mask layer M4 as an implantation mask, such that each heavily doped p-type region 118 has a top-view pattern or geometry inheriting the top-view pattern or geometry of the corresponding opening O4 of the patterned mask layer M4. In this way, the top-view pattern of the opening O4 can be designed to define a desired top-view pattern of the heavily doped p-type region 118. In some embodiments, the p-type ion implantation process IMP4 is performed to implant the p-type impurity at a dose of about 1E14 atoms/cm² to about 1E15 atoms/cm², and at an energy of about 10 KeV to about 50 KeV. The heavily doped p-type regions 118a-118e have a greater p-type impurity concentration than the P-well regions 106a-106e by, for example, at least one order of magnitude.

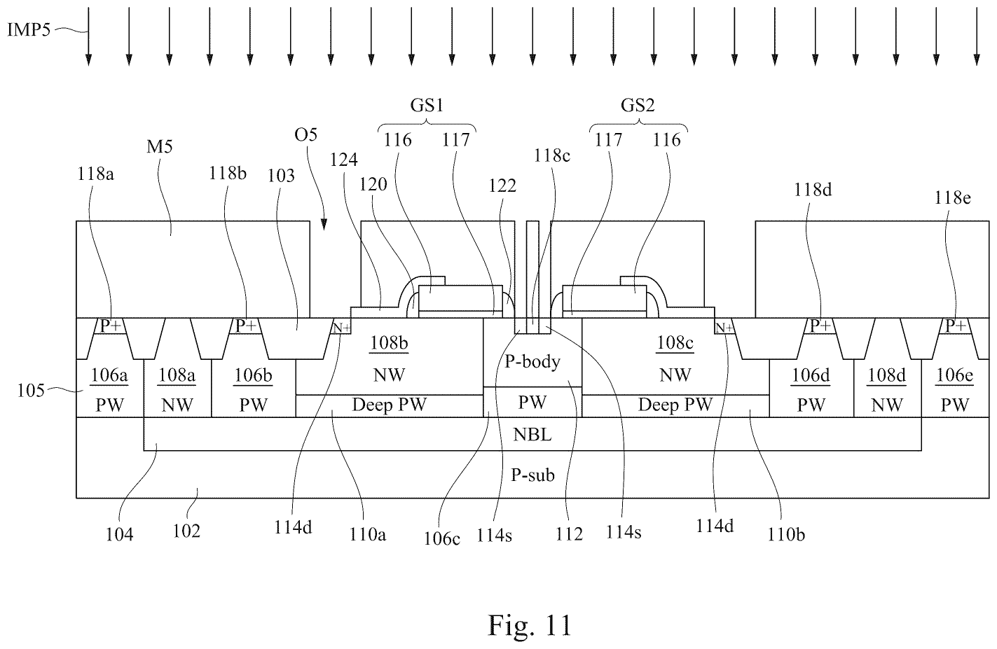

In FIG. 11, after forming the heavily doped p-type regions 118a-118e, the patterned mask layer M4 is removed, for example, using a plasma ash process. In some embodiments, a plasma ash process is performed such that the temperature of the photoresist mask M4 is increased until the photoresist mask M4 experiences a thermal decomposition and may be removed. However, any other suitable process, such as a wet strip, may be utilized.

Next, another patterned mask layer M5 is formed over the p-type epitaxial layer 105 to define locations of n-type source/drain regions 114s/114d formed in subsequent implantation processing. The patterned mask layer M5 may comprise an organic material, such as a photoresist material, and may be formed using a spin-on coating process, followed by patterning the photoresist material, using suitable lithography techniques, to forming one or more openings O5 extending through the patterned mask layer M5 to expose target regions within the p-type epitaxial layer 105. For example, photoresist material is irradiated (exposed) and developed to remove portions of the photoresist material. In greater detail, a photomask (not shown) may be placed over the photoresist material, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist material, and a developer may be used to remove either the exposed or unexposed portions of the photoresist material depending on whether a positive or negative resist is used.

Next, with the patterned mask layer M5 in place, an n-type ion implantation process IMP5 is performed to dope an n-type impurity (e.g., phosphorus, arsenic, antimony, or the like) into the N-well regions 108b, 108c and the p-type body region 112, forming n-type drain regions 114d in the N-well regions 108b, 108c, and forming n-type source regions 114s in the p-type body region 112. The n-type ion implantation IMP5 is performed using the patterned mask layer M5 as an implantation mask, such that each source/drain region has a top-view pattern or geometry inheriting the top-view pattern or geometry of the corresponding opening O5 of the patterned mask layer M5. In this way, the top-view patterns of the openings O5 can be designed to define desired top-view patterns of the n-type source/drain regions 114s/114d. In some embodiments, the n-type ion implantation process IMP5 is performed to implant the n-type impurity at a dose of about 1E14 atoms/cm² to about 1E15 atoms/cm², and at an energy of about 10 KeV to about 50 KeV. The n-type source/drain regions 114s/114d have a greater n-type impurity concentration than the N-well regions 108a-108d by, for example, at least one order of magnitude.

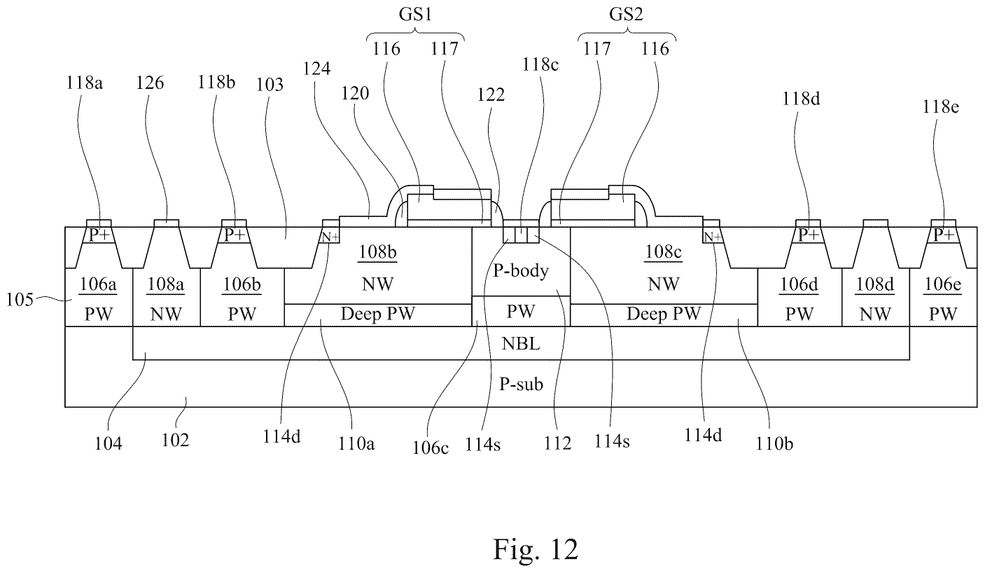

In FIG. 12, silicide regions 126 are formed on the heavily doped p-type regions 118a-118e, the n-type source/drain regions 114s/114d, the N-well regions 108a, 108d, and the exposed top surfaces of the gate electrodes 116, In some embodiments, the silicide regions 126 can be formed by, for example, first depositing a metal (not shown) capable of reacting with the single-crystalline silicon of the underlying p-type epitaxial layer 105 and poly-crystalline silicon of the underlying gate electrodes 116, such as cobalt, titanium, nickel, tantalum, platinum, tungsten, other noble metals, other refractory metals, rare earth metals or their alloys, over the exposed portions of the p-type epitaxial layer 105 and gate electrodes 116, then performing a thermal anneal process to form silicide regions 126. The un-reacted portions of the deposited metal are then removed, e.g., by an etching process. Although the silicide regions 126 are referred to as silicide regions, silicide regions 126 may also be germanide regions, or silicon germanide regions (e.g., regions comprising silicide and germanide), if the p-type epitaxial layer 105 and/or gate electrodes 116 include germanium or silicon germanium.

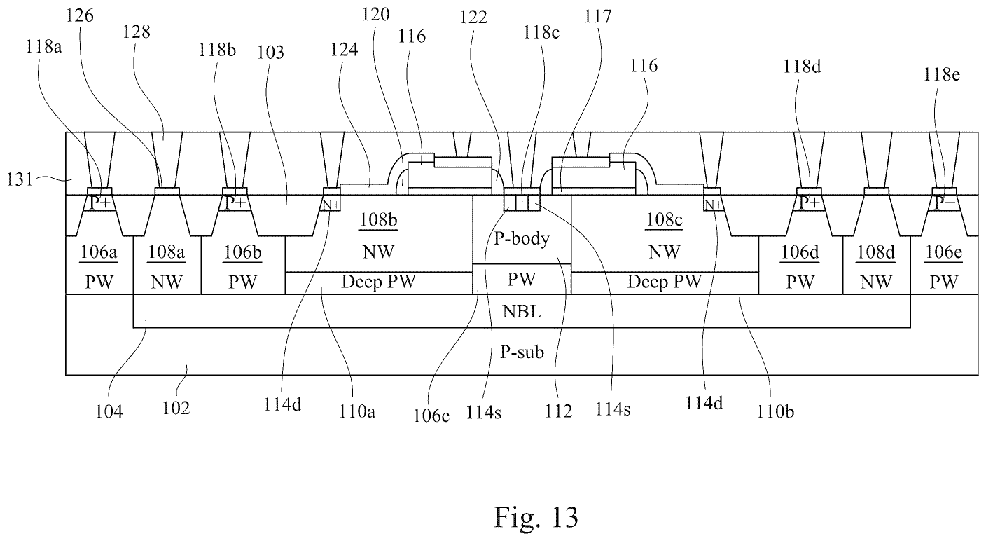

In FIG. 13, an interlayer dielectric (ILD) layer 131 is deposited to span across the HV transistors. The ILD layer 131 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (not shown) is deposited on the gate electrodes 117 and the p-type epitaxial layer 105 prior to depositing the ILD layer 131. The CESL may comprise a dielectric material, such as, silicon nitride, silicon oxide, silicon oxynitride, or the like, having a different etch rate than the material of the overlying ILD layer 131.

Next, metal contacts 128 are formed in the ILD layer 131 to be in contact with the silicide regions 126. These contacts 128 may each comprise one or more metal layers, such as barrier layers, diffusion layers, and fill materials. For example, in some embodiments, the contacts 128 each include a barrier layer and a conductive material, and are electrically coupled to the underlying conductive features (e.g., silicide region). The barrier layer may include titanium, titanium nitride, tantalum, tantalum nitride, or the like. The conductive material may be copper, a copper alloy, silver, gold, tungsten, cobalt, aluminum, nickel, or the like. The metal contacts 128 can be formed by, for example, forming contact openings in the ILD layer 131 using suitable photolithography and etching processes, depositing one or more layers of metal materials in the contact openings, followed by a planarization process, such as a CMP, performed to remove excess metal materials from a surface of the ILD layer 131.

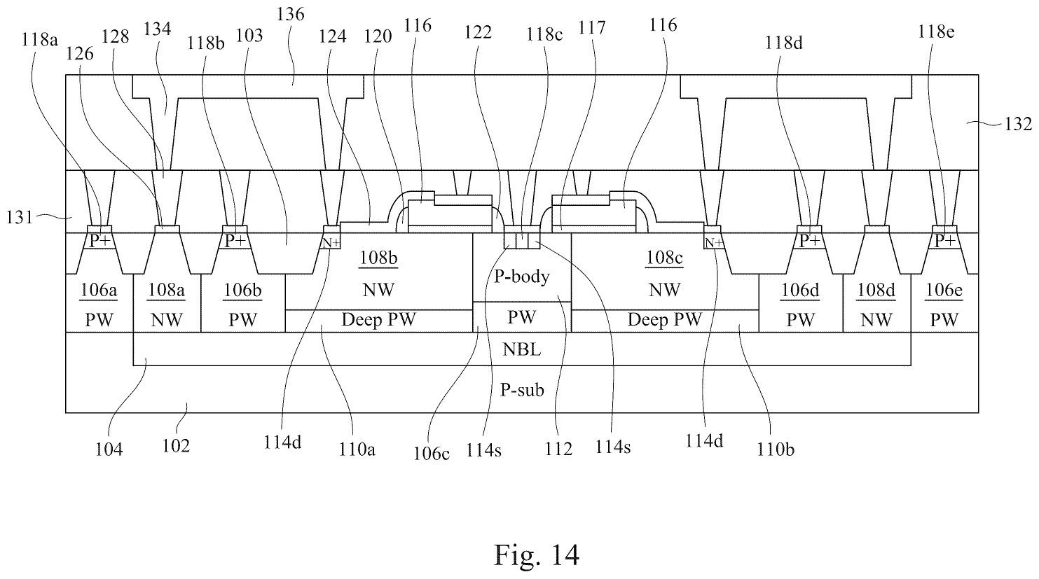

In FIG. 14, another interlayer dielectric (ILD) layer 132 is deposited over the ILD layer 131. The ILD layer 132 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (not shown) is deposited on ILD layer 131 prior to depositing the ILD layer 132. The CESL may comprise a dielectric material, such as, silicon nitride, silicon oxide, silicon oxynitride, or the like, having a different etch rate than the material of the overlying ILD layer 131.

Next, a plurality of metal vias 134 are formed in the ILD layer 132 and over the respective contacts 128, and a plurality of metal lines 136 are formed in the ILD layer 132 and over the metal vias 134. The n-type drain region 114d can be electrically connected to the N-well region 108a by using the metal vias 134 and the metal line 136 that electrically connects the metal via 134. In some embodiments, the metal line 136 is connected to an input voltage terminal. Each of the metal vias 134 and metal lines may comprise a barrier layer and a conductive material. The barrier layer may include titanium, titanium nitride, tantalum, tantalum nitride, or the like. The conductive material may be copper, a copper alloy, silver, gold, tungsten, cobalt, aluminum, nickel, or the like.

The metal vias 134 and metal lines 136 can be formed by using, for example, a dual damascene process, such as forming trenches and contact openings in the ILD layer 132 in a trench-first or via-first approach using suitable photolithography and etching processes, depositing one or more layers of metal materials in the trenches and contact openings. Next, a planarization process, such as a CMP, may be performed to remove excess metal materials from a surface of the ILD layer 132.

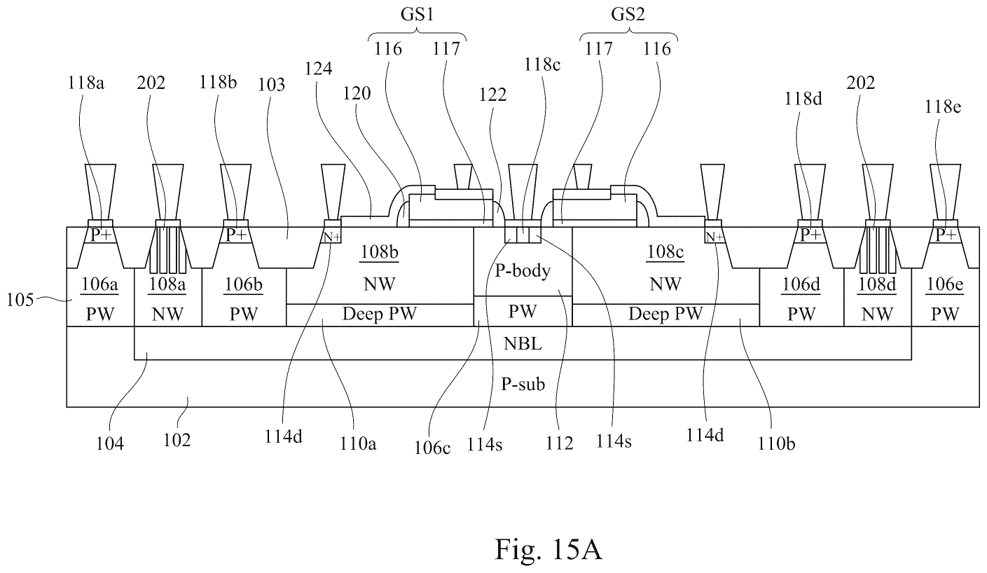

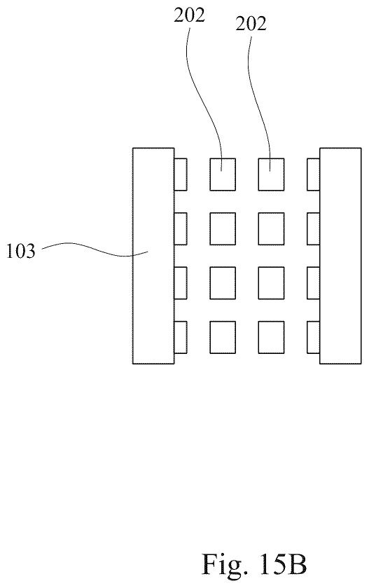

FIG. 15A illustrates a cross-sectional view of an IC structure in accordance with some embodiments of the present disclosure. The structure as illustrated in FIG. 15A is similar to that of FIG. 1, except that the structure in FIG. 15A further includes a plurality of p-type doped regions 202 formed in the N-well region 108a and the N-well region 108d. The p-type doped regions 202 are arranged as a matrix arranged in rows and columns, as illustrated in a top view as illustrated in FIG. 15B. Such arrangement can improve the reverse breakdown voltage of the Schottky diodes formed in the N-well regions 108a, 108d, thereby reducing unwanted leakage currents. In some embodiments, the p-type doped regions 202 have a depth greater than a depth of the STI regions 103, such that bottommost points of the p-type doped regions 202 are lower than bottommost points of the STI regions 103, which in turn further helps in reducing unwanted leakage currents. In some embodiments, the p-type doped regions 202 are formed by performing a p-type ion implantation to dope a p-type impurity (e.g., boron, boron fluoride, indium, or the like) into the N-well regions 108a and 108d.

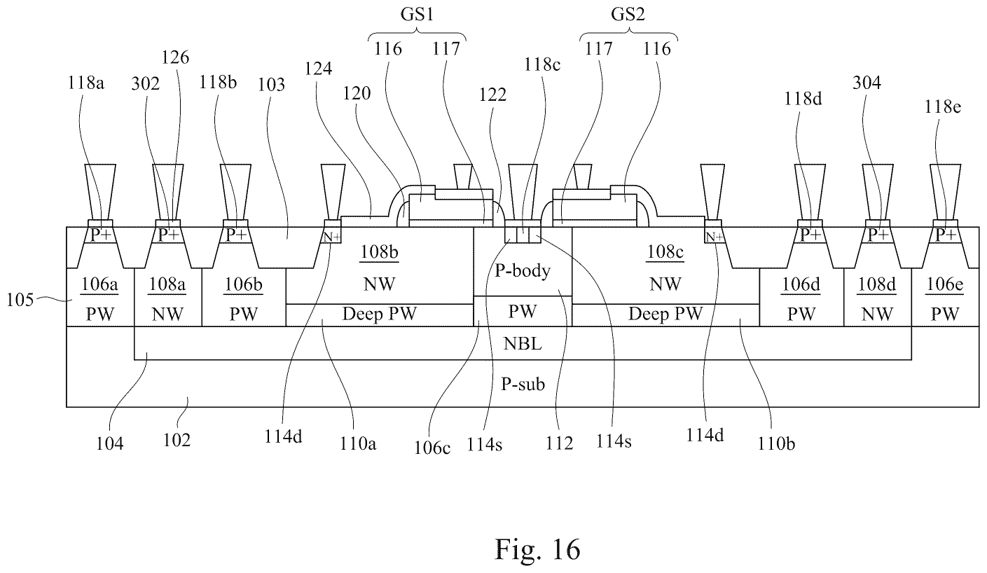

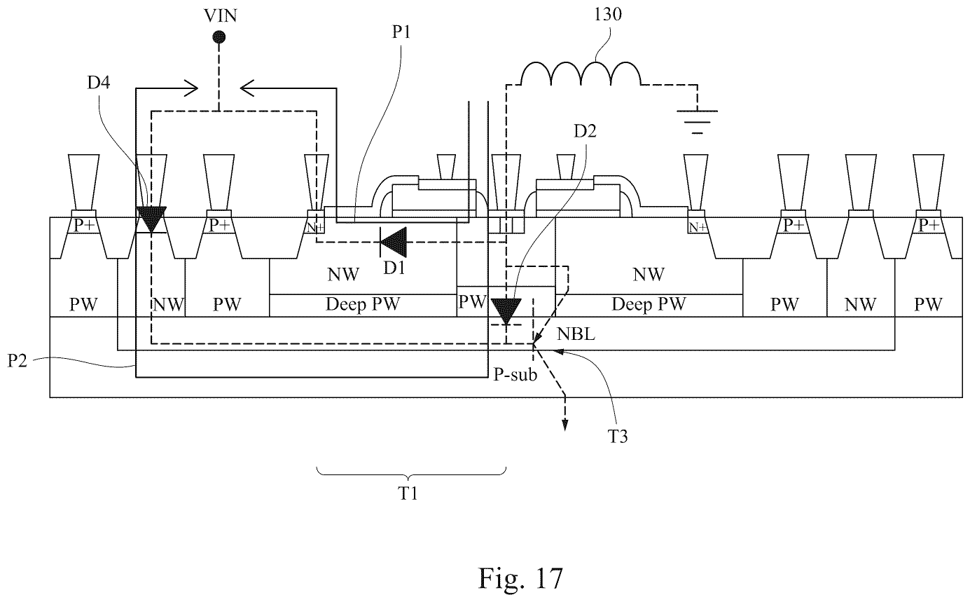

FIG. 16 illustrates a cross-sectional view of an IC structure in accordance with some embodiments of the present disclosure. The structure as illustrated in FIG. 16 is similar to that of FIG. 1, except that the structure in FIG. 16 further includes heavily doped p-type regions 302 and 304 respectively formed in the N-well regions 108a and 108d. In this way, the heavily doped p-type region 302 can form a PN diode with the underlying N-well region 108a, and the heavily doped p-type region 304 can form a PN diode with the underlying N-well region 108d, serving to preventing the parasitic PNP transistor from being turned on. In particular, FIG. 17 is an equivalent circuit diagram of the IC structure as illustrated in FIG. 16. This circuit includes a HV transistor T1 having a source terminal (i.e., the source region 114s) electrically connected to an inductive load 130, and a drain terminal electrically connected to an input voltage terminal (VIN).

When the HV transistor T1 is turned off, the magnetic energy stored in the inductive load 130 seeks a path to dissipate, leading to a reverse current that flows from the inductive load 130 back towards the input voltage terminal VIN. This reverse current can traverse through two paths, labeled P1 and P2. The path P1 runs through a body diode D1 formed from the PN junction of the p-type body region 112 and the N-well region 108b. The path P1 then runs through the n-type drain region 114d and its overlying contact to the input voltage terminal VIN. The path P2 runs through another body diode D2 formed from the PN junction of the P-well region 106c and the NBL 104. The path P2 then runs through the N-well region 108a and its overlying contacts to the input voltage terminal VIN. When the current flows along the path P2, the current flow may inadvertently activate a parasitic PNP transistor T3, which is formed from the deep P-well region 110b, the NBL 104, and the p-type substrate 102. Activation of the parasitic PNP transistor T3 could result in undesirable leakage currents. However, this risk is mitigated by the presence of a PN diode D4, formed from the N-well region 108a and the overlying p-type region 302. When the PN diode D4 is connected in series with the NBL 104 on path P2, the impedance of path P2 significantly increases compared to path P1. This increased impedance effectively discourages current flow through path P2, thereby circumventing the activation of the parasitic PNP transistor T3. As a result, the potential issues related to leakage currents can be reduced.

Moreover, when the HV transistor T1 is turned on, the existence of the PN diode D4 does not adversely impact the circuit's performance. This is due to that the forward voltage drop of the PN diode D3, which is connected to the drain terminal of the HV transistor T1, is low.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the parasitic PNP transistor is prevented from turning on since the conditions that would lead to its activation are mitigated by using the Schottky diode or PN diode connected in series with the NBL. Another advantage is that the risks associated with leakage currents and thermal damage caused by the activation of the parasitic PNP transistor are significantly reduced, preserving the integrity and functionality of the transistors in high-voltage applications.

According to some embodiments, a device includes an n-type buried layer (e.g., layer 104) in a substrate, a first N-well region (e.g., region 108b) over the n-type buried layer, a p-type body region (e.g., region 112) abutting the first N-well region, a first source/drain region (e.g., region 114d) in the first N-well region, a second source/drain region (e.g., region 114s) in the p-type body region, a gate structure (e.g., structure GS1) extending across a boundary of the first N-well region and the p-type body region, a second N-well region (e.g., region 108a) over the n-type buried layer, and a first silicide region (e.g., region 126) forming a Schottky contact with the second N-well region. In some embodiments, the device further includes a second silicide region forming an ohmic contact with the first source/drain region, the second N-well region has a bottommost position lower than a bottommost position of the first N-well region, the first silicide region has a width the same as a width of a top surface of the second N-well region, the second N-well region has a ring-shaped pattern from a top view, and the ring-shaped pattern surrounds the gate structure, the first source/drain region, and the second source/drain region. In some embodiments, the second N-well region has a sidewall aligned with a sidewall of the n-type buried layer, and the second N-well region is in contact with the n-type buried layer. In some embodiments, the second N-well region and the first source/drain region are electrically connected to a same metal line. In some embodiments, the device further includes a plurality of p-type doped regions in the second N-well region, and the p-type doped regions are arranged in rows and columns from a top view.

According to some embodiments, a device includes an n-type buried layer (e.g., layer 104) in a substrate, a first N-well region (e.g., region 108b) over the n-type buried layer, a p-type body region (e.g., region 112) abutting the first N-well region, a first source/drain region (e.g., region 114d) in the first N-well region, a second source/drain region (e.g., region 114s) in the p-type body region, a gate structure (e.g., structure GS1) extending across a boundary of the first N-well region and the p-type body region, a second N-well region (e.g., region 108a) over the n-type buried layer, a p-type region (e.g., 302) over the second N-well region, and a first silicide region (e.g., 126) interfacing the p-type region. In some embodiments, the device further includes a first STI region over a first sidewall of the second N-well region, and a second STI region over a second sidewall of the second N-well region, and the p-type region continuously extends from the first STI region to the second STI region. In some embodiments, the second N-well region is in contact with a top surface of the n-type buried layer.

According to some embodiments, a method includes following steps. A buried layer (e.g., layer 104) is formed in a substrate. The buried layer is of a first conductivity type. An epitaxial layer (e.g., layer 105) is formed over the buried layer. A first well region (e.g., region 108b) and a second well region (e.g., region 108a) are formed in the epitaxial layer. The first and second well regions are of the first conductivity type. A body region (e.g., e.g., region 112) is formed over the buried layer. The body region forms a PN junction with the first well region. A first source/drain region (e.g., region 114d) is formed in the first well region, and a second source/drain region (e.g., region 114s) is formed in the body region. A gate structure (e.g., structure GS1) is formed laterally between the first source/drain region and the second source/drain region. A first silicide region is formed in contact with the second well region. The method further includes forming a second silicide region in contact with the first source/drain region. The method further includes forming a metal line electrically connecting the first silicide region and the second silicide region. In some embodiments, the gate structure extends across a boundary of the body region and the first well region. In some embodiments, the method further includes forming a deep well region below the first well region, the deep well region is of a second conductivity type different than the first conductivity type, and the deep well region is in contact with a top surface of the buried layer. In some embodiments, the substrate is of the second conductivity type.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
an n-type buried layer in a substrate;
a first N-well region over the n-type buried layer;
a p-type body region abutting the first N-well region;
a first source/drain region in the first N-well region;
a second source/drain region in the p-type body region;
a gate structure extending across a boundary of the first N-well region and the p-type body region;
a second N-well region over the n-type buried layer; and
a first silicide region forming a Schottky contact with the second N-well region.

2. The device of claim 1, further comprising:
a second silicide region forming an ohmic contact with the first source/drain region.

3. The device of claim 1, wherein the second N-well region has a bottommost position lower than a bottommost position of the first N-well region.

4. The device of claim 1, wherein the first silicide region has a width the same as a width of a top surface of the second N-well region.

5. The device of claim 1, wherein the second N-well region has a ring-shaped pattern from a top view.

6. The device of claim 5, wherein the ring-shaped pattern surrounds the gate structure, the first source/drain region, and the second source/drain region.

7. The device of claim 1, wherein the second N-well region has a sidewall aligned with a sidewall of the n-type buried layer.

8. The device of claim 1, wherein the second N-well region is in contact with the n-type buried layer.

9. The device of claim 1, wherein the second N-well region and the first source/drain region are electrically connected to a same metal line.

10. The device of claim 1, further comprising:
a plurality of p-type doped regions in the second N-well region, the plurality of p-type doped regions are arranged in rows and columns from a top view.

11. A device, comprising:
an n-type buried layer in a substrate;
a first N-well region over the n-type buried layer;
a p-type body region abutting the first N-well region;
a first source/drain region in the first N-well region;
a second source/drain region in the p-type body region;
a gate structure extending across a boundary of the first N-well region and the p-type body region;
a second N-well region over the n-type buried layer;
a p-type region over the second N-well region; and
a first silicide region interfacing the p-type region.

12. The device of claim 11, further comprising:
a first shallow trench isolation (STI) region over a first sidewall of the second N-well region; and
a second STI region over a second sidewall of the second N-well region.

13. The device of claim 12, wherein the p-type region continuously extends from the first STI region to the second STI region.

14. The device of claim 11, wherein the second N-well region is in contact with a top surface of the n-type buried layer.

15. A method, comprising:
forming a buried layer in a substrate, the buried layer being of a first conductivity type;
forming an epitaxial layer over the buried layer;
forming a first well region and a second well region in the epitaxial layer, the first and second well regions being of the first conductivity type;
forming a body region over the buried layer, the body region forming a PN junction with the first well region;
forming a first source/drain region in the first well region, and a second source/drain region in the body region;
forming a gate structure laterally between the first source/drain region and the second source/drain region; and
forming a first silicide region in contact with the second well region.

16. The method of claim 15, further comprising:
forming a second silicide region in contact with the first source/drain region.

17. The method of claim 16, further comprising:
forming a metal line electrically connecting the first silicide region and the second silicide region.

18. The method of claim 15, wherein the gate structure extends across a boundary of the body region and the first well region.

19. The method of claim 15, further comprising:
forming a deep well region below the first well region, wherein the deep well region is of a second conductivity type different than the first conductivity type, and the deep well region is in contact with a top surface of the buried layer.

20. The method of claim 19, wherein the substrate is of the second conductivity type.
